(19) United States
(12) Patent Application Publication
(10) Pub. No.: US 2011/0041887 A1
(43) Pub. Date: Feb. 24, 2011

(54) THERMOELECTRIC GENERATION APPARATUS

(75) Inventor: Koh Takahashi, Tokyo (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: Universal Entertainment Corporation, Tokyo (JP)

(21) Appl. No.: 12/989,766

(22) PCT Filed: Apr. 28, 2009
(86) PCT No.: PCT/JP2009/058380

§ 371 Date: Oct. 26, 2010

(30) Foreign Application Priority Data
May 12, 2008 (JP) 2008124294

(51) Int. Cl. H01L 35/30

(52) U.S. Cl. 136/212

(57) ABSTRACT

A thermoelectric generation apparatus, which is provided with a thermoelectric conversion element, can be used even when exposed to a high-temperature environment such as being heated on an open fire, and is inexpensive. Onto the bottom surface or the like of a container (11) which can be used even when heated by heat from an ignition source, the thermoelectric conversion element (12) made from the same material which can be used even when heated by the heat generated from the ignition source is installed fixedly. Thus, a thermoelectric conversion apparatus (10), which can be used even when exposed to the high-temperature environment such as an open fire, and is inexpensive, is provided.

### TECHNICAL FIELD

The present invention relates to a thermoelectric generation apparatus provided with a low cost thermoelectric conversion element that can be used even under an open fire.

### BACKGROUND ART

Thermoelectric conversion indicates mutually converting heat energy and electric energy using the Seebeck effect and Peltier effect. If using thermoelectric conversion, it is possible to produce electric power from heat flow using the Seebeck effect. Furthermore, it is possible to bring about a cooling phenomenon by way of heat absorption by flowing electric current in a material using the Peltier effect. This thermoelectric conversion does not cause excess waste product to be emitted during energy conversion due to being direct conversion. Furthermore, it has various benefits in that equipment inspection and the like is not required since moving devices such as motors and turbines are not required, and thus has received attention as a high efficiency application technology of energy.

A thermoelectric conversion element applying such a thermoelectric conversion characteristic is used in various generation apparatuses, charging devices, etc. For example, a thermoelectric conversion element that excels in thermal stability, chemical durability, etc. has been proposed (refer to Japanese Unexamined Patent Application Publication No. 2006-49796). According to this thermoelectric conversion element, in addition to being able to use waste heat such as of a factory, incinerator, steam and nuclear power plants, and any kind of fuel cell or co-generation system, it is possible to put to practical use in thermoelectric power generation using the heat of an automobile engine or to use as an electrical source for mobile devices such mobile phones and notebook personal computers.

### DISCLOSURE OF THE INVENTION

### Problems to be Solved by the Invention

However, the thermoelectric conversion element proposed in Japanese Unexamined Patent Application Publication No. 2006-49796 uses a thermoelectric conversion element employing a cobalt-containing oxide, and is not practical from the point of making thermoelectric conversion elements widely used because cobalt, which is the main component thereof, is expensive. As a result, it is beneficial to develop a thermoelectric generation apparatus provided with a low cost thermoelectric conversion element having high heat resistance to an extent of being able to be used even under an open fire, for example.

The present invention was made taking into account the above-mentioned problems, and an object thereof is to provided a thermoelectric generation apparatus provided with low cost thermoelectric conversion elements that can be used even in a case of being exposed to a high temperature environment equivalent to under an open fire.

### Means for Solving the Problems

The present inventors have conducted extensive research to solve the above-mentioned problems. As a result thereof, they found that a low cost thermoelectric conversion apparatus could be obtained by placing and fixing thermoelectric conversion elements composed of the same material that can be used even if heated by generated heat from an ignition source on a bottom face or the like of a container that can be used even if heated by generated heat from an ignition source, thereby arriving at completion of the present invention. More specifically, the present invention provides the following.

A thermoelectric generation apparatus according to a first aspect includes: a container having a surface opposing an ignition source that can be used even by being heated by way of generated heat from the ignition source; and a thermoelectric conversion element that is placed, interposing an insulating material, on the surface of the container opposing the ignition source, and can be used even by being heated by way of generated heat from the ignition source, in which the thermoelectric conversion element has at least one single element composed of the same raw material, and a conductive member that is electrically connected with the single element, and in which the single element is configured by a sintered body cell having a heating face opposing the ignition source defined as one face and a cooling face opposing the container defined as a face on an opposite side to the heating face, and generating electricity by way of a temperature differential occurring between the heating face and the cooling face, and a pair of electrodes placed on the heating face and the cooling face, in which the electrode on a side of the heating face and the electrode on a side of the cooling face are electrically connected in series by the conductive member.

According to the thermoelectric generation apparatus as described in the first aspect, since a thermoelectric conversion element is provided that is formed by at least one single element composed of the same material, the manufacturing process thereof can be simplified compared to a thermoelectric generation apparatus provided with thermoelectric conversion elements using conventional p-type semiconductors and n-type semiconductors, a result of which the manufacturing cost can be curbed, whereby it is possible to provide a low cost thermoelectric generation apparatus. In addition, the thermoelectric generation apparatus according to the present invention can allow for power generation by holding a cooling medium such as water in a container under an open fire, since thermoelectric conversion elements are provided that can be used even if heated by generated heat from an ignition source. Furthermore, since power generation is possible irrespective of the location so long as there is an ignition source and a cooling medium such as water, it can be used as a mobile thermoelectric generation apparatus.

According to a thermoelectric generation apparatus of a second aspect, in the thermoelectric generation apparatus as described in the first aspect, the thermoelectric conversion element includes a plurality of the single elements, and the single elements have the electrode on the side of the heating face and the electrode on the side of the cooling face of single elements adjacent to one another electrically connected in series.

According to the thermoelectric generation apparatus as described in the second aspect, since thermoelectric conversion elements are used in which the electrode on the side of the heating face and the electrode on the side of the cooling face of adjacent single elements are electrically connected in series by the conductive member, a large output can be obtained.

According to a thermoelectric generation apparatus of a third aspect, in the thermoelectric generation apparatus as described in the first or second aspect, the thermoelectric conversion elements are opposingly disposed to correspond to a shape of the ignition source.

According to the thermoelectric generation apparatus as described in the third aspect, the thermoelectric conversion elements are opposingly disposed to the ignition source to correspond to the shape of the ignition source, so as to enable effective utilization of generated heat from the ignition source. As a result, the thermoelectric conversion elements can absorb the generated heat from the ignition source with good efficiency, whereby efficient power generation becomes possible and high output is obtained. For example, in a case of using a stove as an ignition source, a plurality of the thermoelectric conversion elements, which are made to correspond to the shape of the stove, are disposed on the circumference thereof.

According to a thermoelectric generation apparatus of a fourth aspect, in the thermoelectric generation apparatus as described in any one of the first to third aspects, the sintered body cell includes a sintered body of a complex metal oxide.

By the thermoelectric generation apparatus as described in the fourth aspect using a sintered body of a complex metal oxide as the sintered body cell, the operational effects of the invention according to the above-mentioned first to third aspects are effectively obtained, as well as being able to improve the durability and mechanical strength. In addition, since the complex metal oxide is low cost, a lower cost thermoelectric generation apparatus can be provided.

According to a thermoelectric generation apparatus of a fifth aspect, in the thermoelectric generation apparatus as described in the fourth aspect, the complex metal oxide contains an alkali earth metal, rare earth metal, and manganese.

The thermoelectric generation apparatus as described in the fifth aspect can further improve heat resistance at high temperatures due to using a complex oxide with an alkali earth metal, rare earth metal, and manganese as constituent elements. As the alkali earth metal element, it is preferable to use calcium, and as the rare earth element, it is preferable to use yttrium or lanthanum. More specifically, a perovskite-type CaMnO₃ system complex oxide or the like are exemplified thereas. The perovskite-type CaMnO₃ system complex oxide is more preferably one represented by the general formula Ca₍₁₋ₓ₎MₓMnO₃ is yttrium or lanthanum, and x is in the range of 0.001 to 0.05).

### EFFECTS OF THE INVENTION

According to the present invention, a thermoelectric generation apparatus can be provided that is equipped with a low cost thermoelectric conversion element having high heat resistance to an extent of being able to be used even under an open fire.

### BRIEF DESCRIPTION OF THE DRAWINGS

FIG. 1A is a perspective view of a thermoelectric generation apparatus according to a first embodiment, and FIG. 1B is a bottom view thereof;

FIG. 2 is a bottom view of a thermoelectric generation apparatus according to a modified example of the first embodiment;

FIG. 3A is a perspective view of a thermoelectric generation apparatus according to a second embodiment, and FIG. 3B is a bottom view thereof;

FIG. 4 is a graph showing a relationship between the temperature and open voltage of Example 1; and

FIG. 5 is a graph showing a relationship between the temperature and output of Example 1.

### EXPLANATION OF REFERENCE NUMERALS

10, 20, 30 thermoelectric generation apparatus
11, 21, 32 container
12, 22, 32 thermoelectric conversion element
12A, 12B, 32A, 32B electrode
12C, 32C sintered body cell
12D conductive member
13, 33 insulating member

### PREFERRED MODE FOR CARRYING OUT THE INVENTION

Embodiments of the present invention will be explained below with reference to the drawings. It should be noted that, for configurations that are common with the first embodiment, explanations thereof are omitted as appropriate.

### First Embodiment

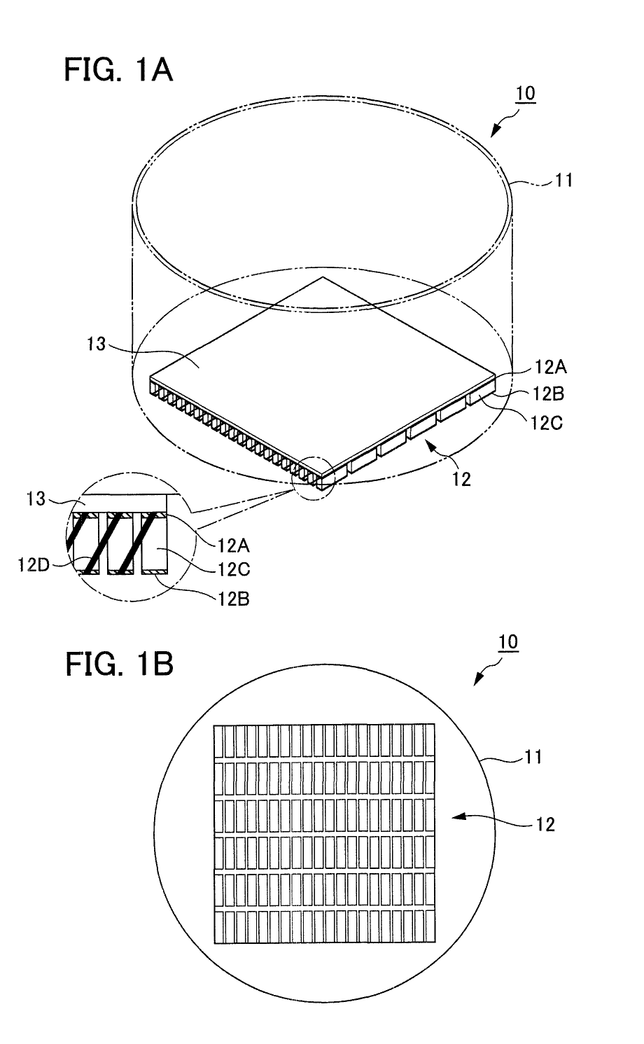

A perspective view of a thermoelectric generation apparatus 10 according to a first embodiment of the present invention is shown in FIG. 1A, and a bottom view thereof is shown in FIG. 1B. As shown in FIGS. 1A and 1B, the thermoelectric generation apparatus 10 according to the first embodiment includes a container 11 that can be used even if a surface thereof opposing an ignition surface is heated by generated heat from the ignition source, and a thermoelectric conversion element 12 that is disposed, interposing an insulating member 13, at a surface of the container 11 opposing the ignition source and that can be used even if being heated by generated heat from the ignition source.

### Container

The container 11 used in the present embodiment is not particularly limited so long as being a container having a surface opposing an ignition source that can be used even if heated by generated heat from the ignition surface and being able to accommodate a cooling medium surface such as water. The shape and size of the container 11 are not particularly limited as well. More specifically, a container such as any kind of a pot or pan for cooking made of metal or ceramic using an ignition source in everyday life is exemplified.

### Insulating Member

The insulating member 13 is not particularly limited so long as being able to maintain electrical insulation properties. More specifically, it is preferable to use a material having favorable heat conductivity for which melting, damage, etc. does not occur at high temperatures on the order of 400° C. or higher, and that is chemically stable and does not react with the thermoelectric conversion element 12, adhesive, etc. A larger electromotive force is obtained by using an insulating member 13 having high heat conductivity. In addition, in the case of using a complex oxide as the thermoelectric element 12 as in the present embodiment, it is preferable to use an insulating member 13 composed of a ceramic oxide such as alumina from the view of thermal expansion coefficient and the like.

### Thermoelectric Conversion Element

The thermoelectric conversion element 12 used in the present embodiment includes a plurality of single elements composed of a sintered body cell 12C, and a pair of electrodes 12A and 12B attached to a heating face, which is defined as one face of this sintered body cell, and a cooling face, which is defined as a face on an opposite side to the heating face. In addition, the thermoelectric conversion element 12 is provided with a conductive member 12D for electrically connecting with another electrode that is different from the electrodes 12A and 12B, and a metallic layer (not illustrated) composed of at least one metal among gold and platinum, and the pair of electrodes 12A and 12B and the conductive member 12D are electrically connected via this metallic layer. Furthermore, the plurality of single elements is systematically aligned to be disposed in substantially a square shape, and the electrode of the heating face side and the electrode of the cooling face side of single elements adjacent to each other are electrically connected in series by the conductive members 12D.

### Sintered Body Cell

The sintered body cell 12C used in the present embodiment is formed from a conventional well-known thermoelectric conversion material. As the thermoelectric conversion material, a sintered body composed of a bismuth-tellurium compound, silica-germanium compound, complex metal oxide, or the like are exemplified. Among these, it is preferable to use a sintered body of a complex metal oxide that can cause heat resistance and mechanical strength to improve. In addition, since complex metal oxides are inexpensive, it is possible to provide a thermoelectric conversion element 12 of lower cost.

Although the shape of the sintered body cell 12C is suitably selected to match the shape of the thermoelectric element 12 and a desired conversion efficiency, it is preferably a rectangular solid or cube. For example, the size of the heating face and cooling face is preferably 5 to 20 mm×1 to 5 mm, and the height is preferably 5 to 20 mm.

A complex metal oxide containing an alkali earth metal, rare earth element, and manganese as constituent elements is preferably used as the complex metal oxide constituting the sintered body cell 12C. According to such a complex metal oxide, a thermoelectric conversion element 12 having high heat resistance and excelling in thermoelectric conversion efficiency is obtained. Above all, it is preferable to use a complex metal oxide represented by the following general formula (I).

Ca₍₁₋ₓ₎MₓMnO₃ (1)

In formula (I), M is at least one element selected from among yttrium and lanthanoids, and x is a range of 0.001 to 0.05.

An example of a production method of the sintered body cell 12C composed of a complex metal oxide represented by the above general formula (I) will be explained. First, CaCO₃, MnCO₃, and Y₂O₃ are added into a mixing pot in which pulverizing balls have been placed, purified water is further added thereto, and the contents of the mixing pot are mixed by mounting this mixing pot to a vibrating ball mill and causing to vibrate for 1 to 5 hours. The mixture thus obtained is filtered and dried, and the dried mixture is preliminarily calcined in an electric furnace for 2 to 10 hours at 900 to 1100° C. The preliminarily calcined body thus obtained by preliminarily calcining is pulverized with a vibrating mill, and the ground product is filtered and dried. A binder is added to the ground product after drying, and then granulated by grading after drying. Thereafter, the granules thus obtained are molded in a press, and the compact thus obtained undergoes main calculation in an electric furnace for 2 to 10 hours at 1100 to 1300° C. From this, a CaMnO₃ system sintered body cell 12C represented by the above general formula (I) is obtained.

Herein, by holding the sintered body cell 12C with two copper plates and establishing a temperature differential of 5° C. between the upper and lower copper plates by heating the lower copper plate using a hot plate, the Seebeck coefficient α of the sintered body cell 12C obtained by the above-mentioned production method can be measured from the voltage generated between upper and lower copper plates. In addition, the resistivity ρ can be measured by the four-terminal method using a digital volt meter.

For example, when measuring the Seebeck coefficient of the CaMnO₃ system sintered body cell 12C represented by the above general formula (I), a high value of at least 100 μV/K is obtained. It is preferable if x is within the range of 0.001 to 0.05 for the composition represented by the above general formula (I), because a high value for the Seebeck coefficient α and resistivity ρ will be obtained.

### Electrodes

The pair of electrodes 12A and 12B are respectively formed at the heating surface, which is defined as a face of one side of the sintered body cell 12C, and the cooling face, which is defined as a face of an opposite side. Conventional well-known electrodes can be used as the pair of electrodes 12A and 12B without being particularly limited. For example, a copper electrode, composed of a metallic body to which a plating process has been performed or a ceramic plate to which a metallization process has been performed, is formed by electrically connecting to the sintered body cell 12C using solder or the like, so that a temperature differential arises smoothly at both ends of the heating face and cooling face of the sintered body cell 12C.

Preferably, the pair of electrodes 12A and 12B is formed by a method of coating a conductive paste on the heating face and cooling face of the sintered body cell 12C, and sintering. The coating method is not particularly limited, and coating methods by a paint brush, roller, or spraying are exemplified, and a screen printing method or the like can also be applied. The calcining temperature when sintering is preferably 200° C. to 800° C., and more preferably 400° C. to 600° C. The calcining time is preferably 10 to 60 minutes, and more preferably 30 to 60 minutes. In addition, calcining preferably raises the temperature step-wise in order to avoid explosive boiling. The thickness of the electrodes formed in this way is preferably 1 μm to 10 μm, and more preferably 2 μm to 5 μm.

For example, a paste containing (A) 70 to 92 parts by mass of fine grains (powder) of metal, (B) 7 to 15 parts by mass of water or an organic solvent, and (C) 1 to 15 parts by mass of an organic binder can be used as the conductive paste used in the formation of the pair of electrodes 12A and 12B Herein, as the fine grains of metal (A), fine grains of silver, copper, nickel, platinum, gold, alumina, and the like are exemplified. Among these, a periodic table group 11 element exhibiting higher electrical conductivity is preferred, it is more preferable to use at least any metal among gold, silver, or copper, and it is more preferably to use silver or copper. The shape of the fine grains can be made into various shapes such as spherical, elliptical, columnar, scale-shaped, and fiber-shaped. The average particle size of the fine grains of metal is 1 nm to 100 nm, preferably 1 nm to 50 nm, and more preferably 1 nm to 10 nm. By using fine grains having such an average particle size, a thinner film can be formed, and a layer that is more precise and having high surface smoothness can be formed. In addition, the surface energy of fine grains having such a nano-sized average particle size exhibits a high value compared to the surface energy of grains in a bulk state. As a result, it becomes possible to carry out sinter formation at a far lower temperature than the melting point of the metal by itself, and thus the manufacturing process can be simplified.

In addition, dioxane, hexane, toluene, cyclohexanone, ethyl cellosolve, butyl cellosolve, butyl cellosolve acetate, butyl carbitol acetate, diethylene glycol diethyl ether, diacetone alcohol, terpineol, benzyl alcohol, diethyl phthalate, and the like are exemplified as the organic solvent (B). These can be used individually or by combining at least two thereof.

As the organic binder (C), that having a good thermolysis property is preferred, and cellulose derivatives such as methylcellulose, ethyl cellulose, carboxymethyl cellulose; polyvinyl alcohols; polyvinyl pyrolidones; acrylic resins; vinyl acetate-acrylic ester copolymer; butyral resin derivatives such as polyvinyl butyral; alkyd resins such as phenol-modified alkyd resin and caster oil-derived fatty acid-modified alkyd resins; and the like are exemplified. These can be used individually or by combining at least two thereof. Among these, cellulose derivatives are preferably used, and ethyl cellulose is more preferably used. In addition, other additives such as glass frit, a dispersion stabilizer, an antifoaming agent, and a coupling agent can be blended as necessary.

The conductive paste can be produced by sufficiently mixing the aforementioned components (A) to (C) according to a usual method, then performing a kneading process by way of a dispersion mill, kneader, three-roll mill, pot mill, or the like, and subsequently decompressing and defoaming. The viscosity of the conductive paste is not particular limited, and is appropriately adjusted to a desired viscosity for use.

According to the electrode formation method using the above such conductive paste, the pair of electrodes 12A and 12B can be formed more thinly. In addition, since it is not necessary to use a binder or the like as is conventionally, a decline in the thermal conductivity and electrical conductivity can be avoided, and the thermoelectric conversion efficiency can be raised further. Furthermore, the structure of the thermoelectric conversion element 12 can be simplified by integrating the sintered body cell 12C with the pair of electrodes 12A and 12B.

### Conductive Member

The conductive member 12D is not particularly limited, and a conventional well-known member of gold, silver, nickel or the like is used thereas. Among these, nickel is particularly preferred from the aspect of cost. Since the conductive member 12D also has high thermal conductivity, it is preferable to make it difficult for heat to be conducted by making the cross-sectional area of the conductive member 12D small, in order to avoid conduction of heat. More specifically, the ratio of the area of the electrode 12A or 12B to the cross-sectional area of the conductive member 12D is preferably 50:1 to 500:1. If the cross-sectional area of the conductive member 12D is too large and outside of the above-mentioned range, heat will be conducted and the necessary heat differential will riot be obtained, and if the cross-sectional area of the conductive member 12D is too small and outside the above-mentioned range, electric current will not be able to flow as well as the mechanical strength thereof being inferior.

### Modification

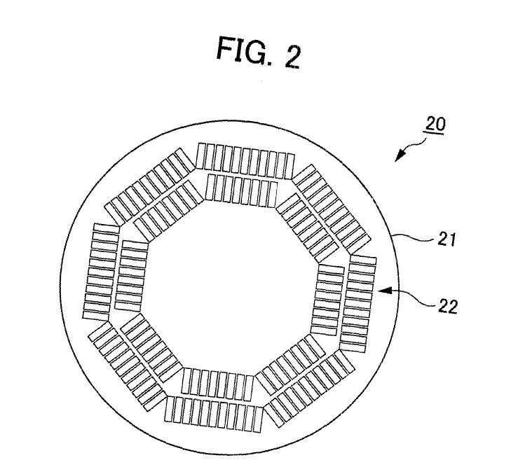

A bottom view of a thermoelectric generation apparatus 20 according to a modification of the first embodiment of the present invention is shown in FIG. 2. As shown in FIG. 2, each constitutional element of the thermoelectric generation apparatus 20 is similar to the first embodiment, and only the arrangement of thermoelectric conversion elements 22 differs. In other words, with the thermoelectric generation apparatus 10 of the first embodiment, a plurality of single elements are systematically aligned to be disposed in substantially a square shape; whereas, with the thermoelectric generation apparatus 20 of the present modification, they are aligned to be arranged on substantially a circumference. This assumes a case of using a stove as the ignition source, and the thermoelectric conversion elements 22 are arranged so as to be opposingly disposed to correspond to the shape of the stove. Therefore, according to the thermoelectric generation apparatus 20, in addition to effects similar to the first embodiment being obtained, heat from the ignition source is more efficiently conducted to the thermoelectric conversion elements 22 since the thermoelectric conversion elements 22 are opposingly disposed to correspond to the shape of the ignition source (stove), a result of which the thermoelectric conversion efficiency can be improved.

### Second Embodiment

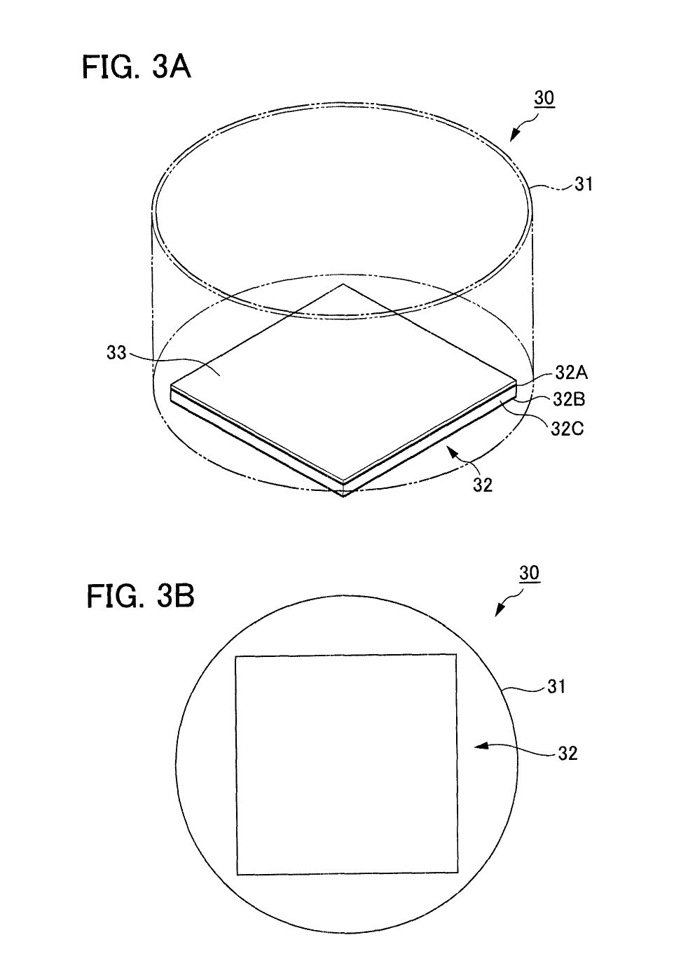

A perspective view of a thermoelectric generation apparatus 30 according to a second embodiment of the present invention is shown in FIG. 3A, and a bottom view thereof is shown in FIG. 3B. Each constituent element of the thermoelectric generation apparatus 30 is similar to the first embodiment; however, the aspect of the thermoelectric conversion element 32 being formed in one single element differs. In other words, with the thermoelectric generation apparatus 10 of the first embodiment, a plurality of single elements is disposed to be systematically aligned and the pair of electrodes of adjacent single elements are electrically disposed in series by conductive members; whereas, with the thermoelectric conversion apparatus 30 of the second embodiment, the thermoelectric conversion element 32 is formed in one single element. Therefore, according to the thermoelectric conversion apparatus 30, in addition to effects similar to the first embodiment being obtained, since the structure is simple, the manufacturing process can be simplified, which can contribute to a reduction in manufacturing cost, a result of which a lower cost thermoelectric generation apparatus can be obtained.

### EXAMPLES

### Example 1

### Production of Thermoelectric Conversion Element

Calcium carbonate, manganese carbonate, and yttrium oxide were weighed so as to make Ca/Mn/Y=0.975/1.0/0.025, and wet mixing was performed for 18 hours by way of a ball mill. Thereafter, filtration and drying was performed, and calcining was performed in air for 10 hours at 1000° C. After pulverizing, the preliminarily calcined powder thus obtained was molded by a single-axis press at a pressure of 1 t/cm². This was calcined in air for 5 hours at 1200° C. to obtain a Ca_{0.975}Y_{0.025}MnO₃ sintered body cell. The dimensions of this sintered body cell were approximately 8.3 mm×2.45 mm×8.3 mm thick. When the Seebeck coefficient and the resistivity were measured, the Seebeck coefficient was 220 μV/K and the resistivity was 0.011 Ω·cm.

A single element was produced by way of forming electrodes by coating a silver nano-paste made by Harima Chemicals, Inc. (average particle size: 3 nm to 7 nm, viscosity: 50 to 200 Pa·s, solvent: 1-decanol (decyl alcohol)) on the top face and bottom face of this sintered body cell using a paint brush, and baking for 30 minutes at 600° C. The weight of the single element thus produced was 0.70 g, and the element resistance when measured was 0.045 Ω.

A thermoelectric conversion element was obtained by joining the single element thus obtained as described above and a conductive member (connector) composed of nickel metal using conductive paste. As the conductive paste, the above-mentioned silver nano-paste made by Harima Chemicals, Inc. used during electrode formation was used, and joining was performed in a similar way by baking for 30 minutes at 600° C.

### Production of Thermoelectric Generation Apparatus

A thermoelectric generation apparatus was produced by modularizing 120 of the thermoelectric conversion elements obtained as described above by placing and fixing to be systematically aligned on the bottom face of a pot for cooking (12 cm diameter×9 cm tall) in a substantially square shape (20 pieces×6 rows) to interpose an insulating member, and connecting the elements in series by the above-mentioned conductive members having a gold layer. During placement and fixing, thermally conductive double-sided tape (made by Sumitomo 3M, Scotch thermally conductive adhesive transfer tape No. 9882) was used to fix the underside of the elements by ceramic bond (made by Toagosei. Co. Ltd., Aron Ceramics C. C). The module resistance when measured was 7.5 Ω.

### Evaluation

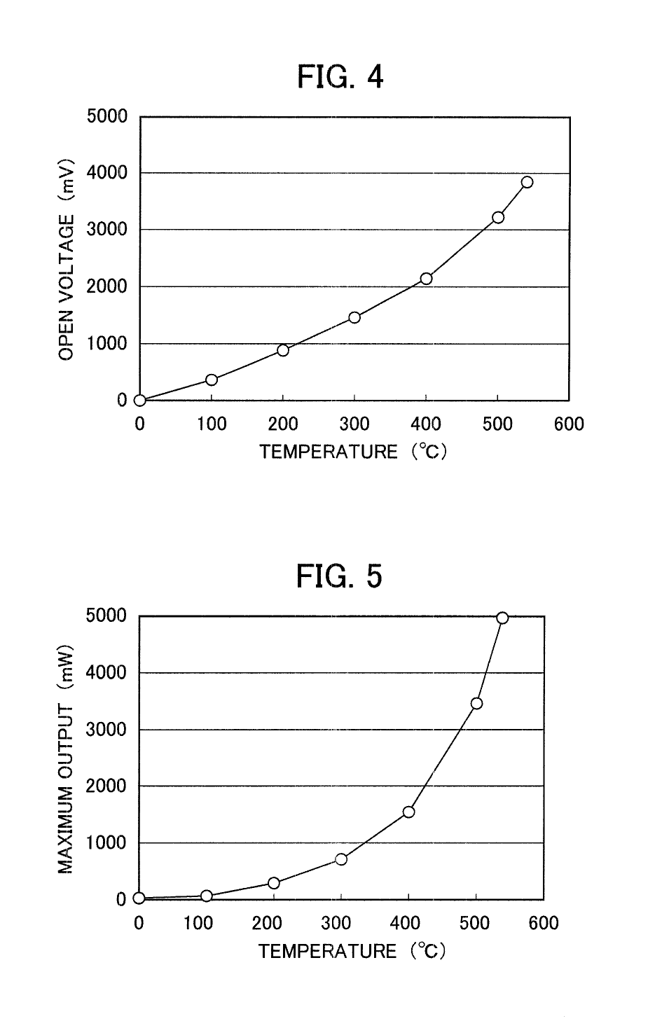

After water of an appropriate amount (approximately 600 ml in the present example) was placed into the container of the thermoelectric generation apparatus thus produced, evaluation of generation performance was performed while heating on a hot plate. The results thereof are shown in FIGS. 4 and 5. FIG. 4 shows a relationship between the plate set temperature and the open voltage, and FIG. 5 shows a relationship between the plate set temperature and maximum output. The water in the container was boiled at a set temperature of the plate of at least 400° C., and a maximum open voltage of 3.86 V and maximum output of 497 mW were obtained at a set temperature of the plate of 540° C. (water in the container boiled violently). This was an output that would allow for satisfactory application as a charger of a mobile telephone or the like.

### Example 2

A thermoelectric conversion apparatus was produced by modularizing 164 of the thermoelectric conversion elements similarly to Example 1 by placing and fixing to be systematically aligned on the bottom face of a pot for cooking (18 cm diameter×7.5 cm tall) on substantially the circumference thereof to interpose an insulating member, and connecting the elements in series by conductive members. In other words, with members except for the pot all set to be similar to Example 1, a thermoelectric conversion apparatus was produced in which only the arrangement of the elements differed from Example 1. The module resistance when measured was 9.5 Ω.

### Evaluation

After water of an appropriate amount (approximately 600 ml in the present example) was placed into the container of the thermoelectric generation apparatus thus produced, evaluation of generation performance was performed when heating on a commercially available table-top gas stove. The water in the container was boiled for several minutes after igniting the table-top gas stove, and evaluation of generation performance was performed when the voltage was stable. As a result thereof, a maximum open voltage of 4.25 V and a maximum output of 475 mW were obtained. Similarly to Example 1, this was an output that would allow for satisfactory application as a charger of a mobile telephone or the like.

1. A thermoelectric generation apparatus comprising: a container having a surface opposing an ignition source that can be used even by being heated by way of generated heat from the ignition source; and a thermoelectric conversion element that is placed, interposing an insulating material, on the surface of the container opposing the ignition source, and can be used even by being heated by way of generated heat from the ignition source,
wherein the thermoelectric conversion element includes at least one single element composed of the same raw material, and a conductive member that is electrically connected with the single element, and
wherein the single element is configured by a sintered body cell having a heating face opposing the ignition source defined as one face and a cooling face opposing the container defined as a face on an opposite side to the heating face, and generating electricity by way of a temperature differential occurring between the heating face and the cooling face, and a pair of electrodes placed on the heating face and the cooling face, in which the electrode on a side of the heating face and the electrode on a side of the cooling face are electrically connected in series by the conductive member.

2. The thermoelectric generation apparatus according to claim 1, wherein the thermoelectric conversion element includes a plurality of the single elements, and wherein the single elements have the electrode on the side of the heating face and the electrode on the side of the cooling face of single elements adjacent to one another electrically connected in series.

3. The thermoelectric generation apparatus according to claim 2, wherein the thermoelectric conversion elements are opposingly disposed to correspond to a shape of the ignition source.

4. The thermoelectric generation apparatus according to claim 1, wherein the sintered body cell includes a sintered body of a complex metal oxide.

5. The thermoelectric generation apparatus according to claim 4, wherein the complex metal oxide contains an alkali earth metal, rare earth metal, and manganese.

6. The thermoelectric generation apparatus according to claim 1, wherein the thermoelectric conversion elements are opposingly disposed to correspond to a shape of the ignition source.

7. The thermoelectric generation apparatus according to claim 6, wherein the sintered body cell includes a sintered body of a complex metal oxide.

8. The thermoelectric generation apparatus according to claim 7, wherein the complex metal oxide contains an alkali earth metal, rare earth metal, and manganese.

9. The thermoelectric generation apparatus according to claim 1, wherein the sintered body cell includes a sintered body of a complex metal oxide.

10. The thermoelectric generation apparatus according to claim 9, wherein the complex metal oxide contains an alkali earth metal, rare earth metal, and manganese.

11. The thermoelectric generation apparatus according to claim 2, wherein the sintered body cell includes a sintered body of a complex metal oxide.

12. The thermoelectric generation apparatus according to claim 11, wherein the complex metal oxide contains an alkali earth metal, rare earth metal, and manganese.
